(19) United States
(12) Patent Application Publication
(10) Pub. No.: US 2026/0260081 A1
(43) Pub. Date: Sep. 3, 2026

(54) An Electronic Device and a Method for Fully Parallel Discrete Fourier-Related Transform

(71) Applicant: Telefonaktiebolaget LM Ericsson (publ), Stockholm (SE)

(72) Inventor: Mojtaba Mahdavi, Lund (SE)

(21) Appl. No.: 19/163,496

(22) PCT Filed: Mar. 24, 2023
(86) PCT No.: PCT/EP2023/057613

§ 371 Date: Sep. 9, 2025

(51) Int. Cl. G06J 1/00

(52) U.S. Cl. CPC G06J 1/005

(57) ABSTRACT

An electronic device (200) comprising a crossbar array (201) comprising N input conductors (231) for receiving an input signal of N samples and a set of output conductors (232) electrically connected to the set of N input conductors via an array of memristors (211, 212, 221, 222). Each memristor (211, 212, 221, 222) is configured to represent a transform coefficient out of N×N/8 sequential transform coefficients. A total number of output conductors utilized for discrete Fourier-related transform of the input signal is 2×N/8 and a total number of utilized memristors (211, 212, 221, 222) is 2×N×N/8 or a total number of output conductors utilized is N/8 and a total number of utilized memristors (211, 212, 221, 222) is N×N/8 when the transform coefficients are real. The crossbar array (201) further comprises an electronic circuit (240) configured to calculate N output samples comprising eight subsets of output samples, and configured to calculate a subset of output samples based on an output from an output conductor and based on a symmetry of the N×N transform coefficients.

### TECHNICAL FIELD

The embodiments herein relate to an electronic device and a method for fully parallel discrete Fourier-related transform. A corresponding computer program and a computer program carrier are also disclosed.

### BACKGROUND

Fourier Transform (FT) and Inverse FT (IFT) is used in various signal processing applications, such as communication signal processing, image and video signal processing and audio processing. High-throughput and real-time processing has become essential demands in such applications.

For purposes of performing the Fourier transform in a digital processing system, the Fourier transform may be performed using a discrete transform, such as a Discrete Fourier Transform (DFT). DFT is extensively used in many applications to perform Fourier analysis.

The DFT is a matrix operation in which a real or complex value input vector, e.g., a vector representing sampled values for a temporally or spatially varying input signal, is transformed into a complex value output vector, which for example is a vector representing frequency and phase components of the input signal. In other words, the DFT may calculate a frequency spectrum of a signal x, such that N discrete-time samples, i.e., x₀, x₁, . . . , x_{N-1}, of signal x are transformed into a same number of discrete-frequency samples, i.e., X₀, X₄, . . . , X_{N-1}, of signal X. This transformation may be expressed mathematically as

$$X ( n ) = {\sum }_{k = 0}^{N - 1} x ( k ) {W}_{N}^{nk} \qquad ( 1 )$$

$$n , k = 0 , … , N - 1 ,$$

where

$${W}_{N}^{nk} = {e}^{- j 2 π nk / N}$$

are coefficients or the DFT, which are called twiddle factors.

An important use case of DFT is to perform orthogonal frequency-division multiplexing (OFDM) in wireless communication systems. Moreover, DFT is used in digital signal processing application including image and video processing.

A key concept in the DFT computation is the decomposition scheme. There are two main decomposition schemes called decimation in time (DIT) and decimation in frequency (DIF). In the DIT scheme, the input sequence is separated into its even- and odd-indexed samples, which breaks down an N-point DFT into two N/2-point DFTs. This process is repeated iteratively for the sub-sequences, i.e., N/2-point DFTs, until the whole sequence is decomposed. However, in the DIF scheme an N-point DFT is decomposed iteratively into DFTs of size N/2 points and the decomposition is started from the output sequence by dividing them into even- and odd-indexed frequencies. Thus, in case of DIF, the samples of input sequence of DFT are in natural order while the output samples are generated in bit-reversed order. In case of DIT, the samples of input sequence of DFT are in bit-reversed order while the output samples are produced in natural order. As a result, a reordering circuit is needed to reorder either the input samples in the DIT or the output samples in the DIF scheme.

Having considered the intensive calculation in equation (1) and also the need for a reordering circuit, the hardware realization of DFT becomes very challenging. Several methods have been presented to reduce the computational complexity of DFT and compute the DFT efficiently, which are commonly referred to as Fast Fourier Transform (FFT) algorithms. FFT algorithms may be implemented in hardware using several architectures, which are discussed below.

Prior art hardware implementations of DFT may be categorized in four groups. These designs as well as the corresponding problems are discussed below.
1. Memory-based architectures, i.e., in-place architectures, consist of one or more processing element (PE) to calculate the computations in equation (1) and the results are saved in one or more memories. One such prior art is for example C.-L. Wey, S.-Y. Lin, W.-C. Tang and M.-T. Shiue, “High-speed, Low Cost Parallel Memory-Based FFT Processors for OFDM Applications,” 2007 14th IEEE International Conference on Electronics, Circuits and Systems, 2007, pp. 783-787, doi: 10.1109/ICECS.2007.4511108. The DFT calculation is done by fetching input samples from the memory, perform the calculation using PEs and storing the results in the memories. This process is performed iteratively to complete the DFT computations. Memory-based architectures suffer from low throughput, which is mainly due to the memory access conflicts and limited memory bandwidth in case of high-level of parallelism. Moreover, this kind of architecture is unable to compute the DFT while data arrive continuously at the input and thus it may not be a good choice for real-time applications.
2. Pipelined architectures are another type of architectures which perform DFT computations continuously while the next input stream enters into the architecture. This group includes single-path delay feedback (SDF) architectures, multi-path delay feedback (MDF) architectures, and multi-path delay commutator (MDC) architectures. The MDF architecture achieves a high throughput by processing multiple data paths at the expense of hardware cost. However, the number of parallel paths is limited due to the hardware cost and complexity.
3. Direct implementation architecture is a fully parallel implementation of the DFT to achieve a high throughput. In this approach, all the computations of the signal flow graph (SFG) of DFT are mapped directly onto the PEs. Therefore, in this kind of architecture the number of PEs is equal to the number of operations. As a result, due to the hardware cost of complex-multiplications and additions, this solution is not efficient for most applications especially for large DFT sizes.
4. Recently, another approach has been proposed to realize the DFT computations in a parallel manner using a memristor crossbar array as a hardware accelerator. A memristor may also be referred to as a memristive device. Analog memristive devices have emerged as a new technology for storing and processing information in analog domain. These devices make it possible to perform computations in a place where data is stored. This concept is called in-memory computing, which eliminates the need for moving data from a memory to a processing unit. There are different types of memristive devices, which are differentiated with respect to the used materials, switching principles, device endurance, retention, etc. The main types of memristive devices include phase change memory (PCM), resistive random-access memory (ReRAM), spin-transfer torque magnetic RAM (STT-MRAM), ferroelectric memristive devices (FeRAM). Memristive devices may support a limited bit precision, attributed to the limited number of conductance levels that may be reliably programmed in the device. For example, a PCM device may support around 50 conductance levels, meaning that it may represent around 6 bits. FIG. 1 illustrates a memristor crossbar array 110 which computes matrix-vector multiplication (MVM) by calculating a dot-product of the input vector applied to crossbar rows (i.e., word lines) and every column of the crossbar (i.e., bit lines). The memristor crossbar array 110 is a two-dimensional array that comprises an M×N array of memristors 111, 112, 121, 122, each of which may be programmed to represent an m-bit binary value. A memristor is a tunable resistor with memory. The memristor may comprise a dielectric layer sandwiched by two electrodes. A unique feature of memristors is that the conductance depends on historical electrical signals, making them capable of working as nonvolatile memory. In addition, memristors may store multibit information with continuously tunable conductance, in contrast to binary states “0” and “1” in traditional digital storage systems, equipping them with higher bit density. Thus, the m-bit binary value of the memristor may be set or programmed by applying a current to the memristor. The binary value may depend on the amplitude of the current. Thus, an M×M matrix of binary words, G, may be represented by the memristor crossbar array 110 comprising M×M memristors. The input to the memristor crossbar array 110 is an electronic input signal of multiple samples, such as a vector of M binary values, e.g., V.
   However, as the input as well as the transform coefficients may be complex the proposed memristor-based schemes in prior art U.S. Pat. No. 10,621,267 B2 require 4N² memristive devices to implement an N-point DFT based on the complex input samples and the complex transform coefficients. Moreover, these designs need N Analog to Digital Converter (ADC) modules and N/2 adders for each N×N memristor crossbar array 110, thus 4N ADC modules and 2N adders for a complex-valued input and complex-valued transform coefficients, to generate the output samples of DFT in parallel. Also, it is not known how these prior art designs may support the DIT scheme. To reduce the hardware cost prior art U.S. Pat. No. 10,621,267 B2 discloses a butterfly approach to implement an N-point DFT using log₂ N stages, each has N/2 butterfly units. According to U.S. Pat. No. 10,621,267 B2, each butterfly unit may be implemented using 16 memristors. Although the number of required memristors is reduced compared to 4N², there are other issues regarding the butterfly-based implementation using crossbars as follows:
   To implement DFT using the approach in prior art U.S. Pat. No. 10,621,267 B2, typical crossbar arrays with a regular structure cannot be used. This is due to the fact that the connections between the butterfly units in different stages vary from one stage to another. Thus, a specific crossbar array should be designed just to perform DFT computation.
   Due to the above-mentioned connections between butterfly units, such an architecture cannot be scaled easily to perform DFT for larger/smaller DFT sizes. This means that a fixed crossbar array should be used for a specific DFT size.
   In a butterfly-based implementation of DFT using crossbars, the output signals of butterfly units should be converted from current to voltage between different DFT stages, which increases the hardware cost.
   As mentioned before, an N-point DFT is realized though log₂ N stages, in which the input signals of each stage come from the previous stage. This increases the total delay of DFT computation specially for large DFT sizes.
   An important issue of the approach in prior art U.S. Pat. No. 10,621,267 B2 is that a reordering circuit is needed to reorder either the input samples in the DIT or the output samples in the DIF schemes. Implementation of such reordering circuit needs two extra crossbars each with N² memristive devices. As a result, the hardware cost and delay will be increased considerably.

### SUMMARY

There is thus a need for a more efficient approach for implementing Fourier-related transforms. An object of embodiments herein may be to obviate some of the problems related to Fourier-related transforms mentioned above.

Embodiments herein disclose an electronic device and methods for fully parallel discrete Fourier-related transforms.

According to a first aspect, the object is achieved by an electronic device for fully parallel discrete Fourier-related transform of an input signal of N multiple samples. N is a natural number of two or more. The electronic device comprises an analog crossbar array comprising a set of N utilized input conductors for receiving N analog voltages corresponding to the input signal of N multiple samples and a set of output conductors electrically connected to the set of N input conductors via an array of memristive devices such that each output conductor is connected to a respective input conductor via a respective memristive device.

Each memristive device is configured to represent at least a part of a respective transform coefficient out of N×N/8 sequential transform coefficients of a total of N×N transform coefficients of the discrete Fourier-related transform.

A total number of output conductors utilized for discrete Fourier-related transform of the input signal of N multiple samples of the set of output conductors is 2×N/8 and a total number of utilized memristive devices of the array of memristive devices is 2×N×N/8 when the transform coefficients are complex. A total number of output conductors utilized is N/8 and a total number of utilized memristive devices of the array of memristive devices is N×N/8 when the transform coefficients are real or imaginary.

The electronic device further comprises an electronic circuit configured to calculate N output samples of the discrete Fourier-related transform comprising eight subsets of output samples, each subset of output samples comprises N/8 output samples, wherein the electronic circuit is configured to calculate a respective subset of output samples based on an output from a respective output conductor of the 2N/8 or N/8 output conductors and further based on a symmetry of the N×N transform coefficients.

According to a second aspect, the object is achieved by a method, performed by an electronic device, for fully parallel discrete Fourier-related transform of an input signal of N multiple samples. N is a natural number of two or more.

The method comprises applying the input signal to an analog crossbar array comprising a set of N utilized input conductors for receiving N analog voltages corresponding to the input signal of N multiple samples and a set of output conductors electrically connected to the set of N input conductors via an array of memristive devices such that each output conductor is connected to a respective input conductor via a respective memristive device.

Each memristive device is configured to represent at least a part of a respective transform coefficient out of N×N/8 sequential transform coefficients of a total of N×N transform coefficients of the discrete Fourier-related transform.

A total number of output conductors utilized for discrete Fourier-related transform of the input signal of N multiple samples of the set of output conductors is 2×N/8 and a total number of utilized memristive devices of the array of memristive devices is 2×N×N/8 when the transform coefficients are complex.

A total number of output conductors utilized is N/8 and a total number of utilized memristive devices of the array of memristive devices is N×N/8 when the transform coefficients are real or imaginary.

The method further comprises calculating N output samples of the discrete Fourier-related transform comprising eight subsets of output samples, each subset of output samples comprises N/8 output samples. Calculating a respective subset of output samples is based on an output from a respective output conductor of the 2N/8 or N/8 output conductors and further based on a symmetry of the N×N transform coefficients.

According to a further aspect, the object is achieved by a computer program comprising instructions, which when executed by a processor, causes the processor to perform actions according to any of the aspects above.

According to a further aspect, the object is achieved by a carrier comprising the computer program of the aspect above, wherein the carrier is one of an electronic signal, an optical signal, an electromagnetic signal, a magnetic signal, an electric signal, a radio signal, a microwave signal, or a computer-readable storage medium.

The electronic device may operate on real or imaginary inputs. If the input is complex then two electronic devices according to the first aspect may be used in combination. One for the real input and one for the imaginary input.

Since the electronic device comprises N×N/8 or 2×N×N/8 utilized memristive devices and comprises the electronic circuit configured to calculate N output samples based on an output from a respective output conductor of the 2N/8 or N/8 output conductors and further based on the symmetry of the N×N transform coefficients the number of required memristive devices is significantly reduced without reducing the degree of parallelism and without throughput degradation.

Embodiments herein support both DIF and DIT decomposition schemes.

Embodiments herein may be implemented on a non-specific memristor crossbar array. That is, the memristor crossbar array does not need to be specific for DFT.

Embodiments herein support different sizes of the transform matrix with the same memristor crossbar array.

Embodiments herein may be implemented without a reordering circuit.

### BRIEF DESCRIPTION OF THE DRAWINGS

In the figures, features that appear in some embodiments are indicated by dashed lines.

The various aspects of embodiments disclosed herein, including particular features and advantages thereof, will be readily understood from the following detailed description and the accompanying drawings, in which:

FIG. 1 is a block diagram schematically illustrating a prior art device for DFT,

FIG. 2a is a block diagram schematically illustrating an electronic device according to some embodiments herein,

FIG. 2b is a block diagram schematically illustrating an electronic device according to some further embodiments herein,

FIG. 3 is a further block diagram schematically illustrating an electronic device according to yet some further embodiments herein,

FIG. 4 is a further block diagram schematically illustrating an adder circuit according to some embodiments herein,

FIG. 5 is a further block diagram schematically illustrating an adder circuit according to some embodiments herein,

FIG. 6 is a further block diagram schematically illustrating a further adder circuit according to some embodiments herein,

FIG. 7 is a coefficient matrix for an adder circuit,

FIG. 8 is a further coefficient matrix for an adder circuit,

FIG. 9 is a further block diagram schematically illustrating a further adder circuit according to some embodiments herein,

FIG. 10 is a flowchart illustrating embodiments of a method for Fourier-related transform performed by an electronic device,

FIG. 11 is a further flowchart illustrating further embodiments of a method for Fourier-related transform performed by an electronic device,

FIG. 12 is a further flowchart illustrating further embodiments of a method for Fourier-related transform performed by an electronic device,

FIG. 13a is a schematic block diagram illustrating embodiments of an electronic device,

FIG. 13b is a schematic block diagram illustrating further embodiments of an electronic device,

FIG. 14 is a schematic block diagram illustrating further embodiments of an electronic device,

FIG. 15 is a block diagram schematically illustrating a wireless communication system.

### DETAILED DESCRIPTION

Embodiments herein relate to electronic signal processing with electronic devices. More specifically, embodiments herein relate to methods and electronic devices for fully parallel discrete Fourier-related transform of an input signal. The Fourier-related transforms may for example be applied in digital communications. Examples of Fourier-related transforms are DFT, Inverse DFT (IDFT), Discrete Cosine Transform (DCT) and Inverse DCT (IDCT). DCT operate on real input samples, while input samples to DFT may be complex.

Although embodiments disclosed herein are applicable to other Fourier-related transforms than DFT and IDFT embodiments herein will mainly be exemplified with DFT and IDFT.

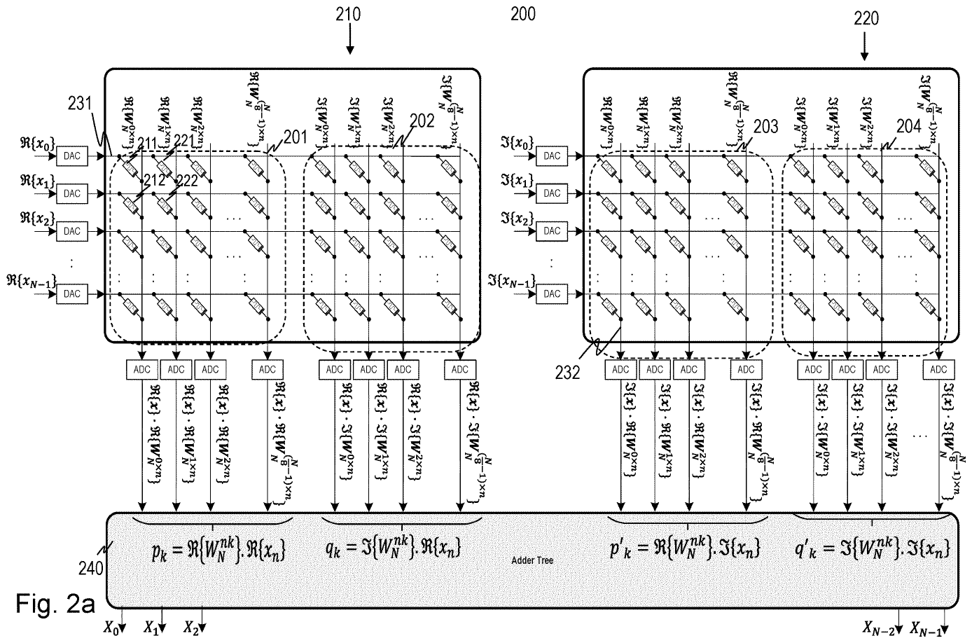

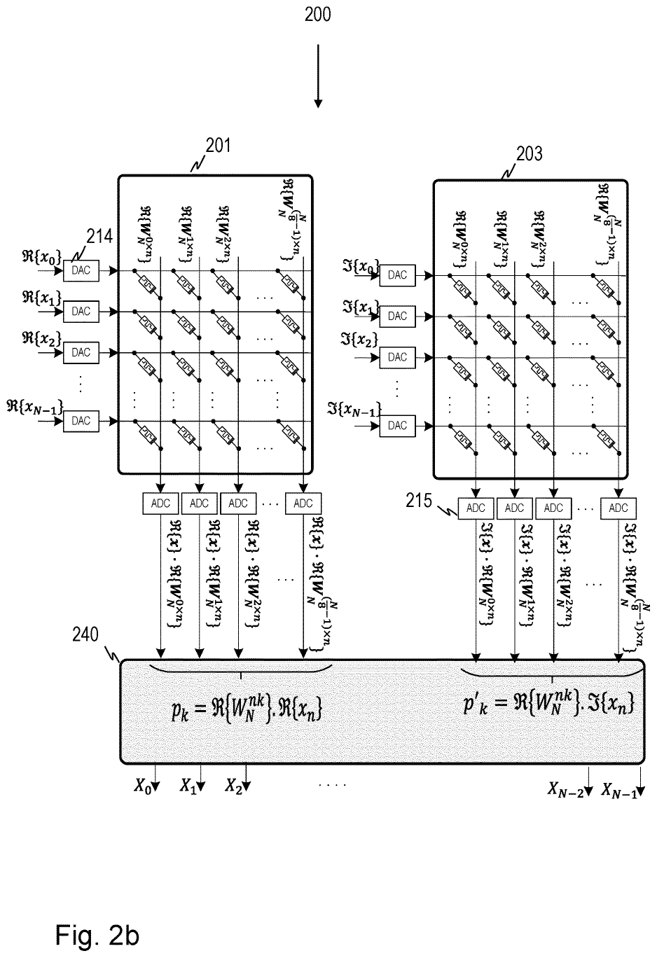

FIG. 2a illustrates an electronic device 200. The electronic device 200 comprises an analog crossbar array 201, 202, 203, 204 comprising memristive devices 211, 212, 221, 222. The electronic device 200 is for fully parallel discrete Fourier-related transform of an input signal. The input signal comprises N multiple samples. N is a natural number of two or more. Depending on the particular implementation, the input signal may be a real value input vector in that the values of the input vector are purely real values and do not contain imaginary components. For example, the input vector may represent discrete samples of a real value signal, such as discrete samples of the amplitude of a time-varying audio signal, discrete samples of the intensity of a spatially varying image signal, and so forth. In accordance with further example implementations, the input vector may be a complex value input vector in that the input vector may contain complex values, i.e., values that have real and imaginary components. For example, the input vector may represent in-phase and quadrature phase components of an angle modulated signal, where the in-phase and quadrature phase components may be represented by real and imaginary components, respectively.

The electronic device 200 may comprise a first electronic device 210 configured to receive a real part of the input signal and a second electronic device 220 configured to receive an imaginary part of the input signal. The second electronic device 220 may comprise corresponding electronic components as the first electronic device 210. The first electronic device 210 comprises one or more first analog crossbar arrays 201, 202 comprising memristive devices 211, 212, 221, 222. The second electronic device 220 comprises one or more second analog crossbar arrays 203, 204 comprising memristive devices. The memristors of the second electronic device 220 may be configured with the same transform coefficients, e.g., twiddle factors, as the memristors of the first electronic device 210. In case the transform coefficients are complex, the analog crossbar array 201, 202, 203, 204 may comprise a first part 201, 203 and a second part 202, 204. The first part 201, 203 may be configured with the real part of the transform coefficients while the second part 202, 204 may be configured with the imaginary part of the transform coefficients.

The analog crossbar array 201, 202, 203, 204 further comprises a set of N utilized input conductors 231 for receiving N analog voltages corresponding to the input signal of N multiple samples.

The analog crossbar array 201, 202, 203, 204 further comprises a set of output conductors 232 electrically connected to the set of N input conductors via an array of memristive devices 211, 212, 221, 222 such that each output conductor 232 is connected to a respective input conductor 231 via a respective memristive device 211, 212, 221, 222.

Each memristive device 211, 212, 221, 222 is configured to represent at least a part of a respective transform coefficient out of N×N/8 sequential transform coefficients of a total of N×N transform coefficients of the discrete Fourier-related transform.

A total number of output conductors utilized for discrete Fourier-related transform of the input signal of N multiple samples of the set of output conductors is 2×N/8 and a total number of utilized memristive devices 211, 212, 221, 222 of the array of memristive devices 211, 212, 221, 222 is 2×N×N/8 when the transform coefficients are complex. A total number of output conductors utilized is N/8 and a total number of utilized memristive devices 211, 212, 221, 222 of the array of memristive devices 211, 212, 221, 222 is N×N/8 when the transform coefficients are real or imaginary.

As mentioned above, in some embodiments herein the transform coefficients are complex. Then the array of utilized 2×N×N/8 memristive devices 211, 212, 221, 222 may comprise a first part 201, 203 of N×N/8 memristive devices connected to N/8 first output conductors and the array of utilized 2×N×N/8 memristive devices 211, 212, 221, 222 may further comprise a second part 202, 204 of N×N/8 memristive devices connected to N/8 second output conductors. Further, when the transform coefficients are complex each memristive device 211, 212, 221, 222 of the first part 201, 203 of N×N/8 memristive devices may be configured to represent a real part of a respective complex transform coefficient out of the N×N/8 sequential transform coefficients of the total of N×N transform coefficients and each memristive device 211, 212, 221, 222 of the second part 202, 204 of N×N/8 memristive devices may be configured to represent an imaginary part of the respective complex transform coefficient out of the N×N/8 sequential transform coefficients.

The crossbar arrays according to embodiments herein enable performing massive multiply-accumulate (MAC) operations in parallel. More specifically, the crossbar arrays may compute matrix-vector multiplication (MVM) by calculating a dot-product of the input vector applied to crossbar rows (i.e., word lines) and every column of the crossbar (i.e., bit lines).

Analog crossbar arrays comprise parallel conductors, such as metal lines, termed word lines and bit lines, respectively, as electrodes of the memristors. The word lines and bit lines may be perpendicular to each other. The memristors are formed at the intersections of word and bit lines. In embodiments herein the input conductors 231 of the analog crossbar array 201, 202, 203, 204 corresponds to the word lines and the output conductors 232 of the analog crossbar array 201, 202, 203, 204 corresponds to the bit lines.

The analog crossbar array 201, 202, 203, 204 computes MVM by calculating the dot-product of the input vector applied to crossbar rows (i.e., word lines) and every column of the crossbar (i.e., bit lines), all performed in analog domain using Ohm's law for multiplication and Kirchhoff's law for accumulation.

Mathematically an N×N transform matrix may be used to calculate a Fourier-related transform.

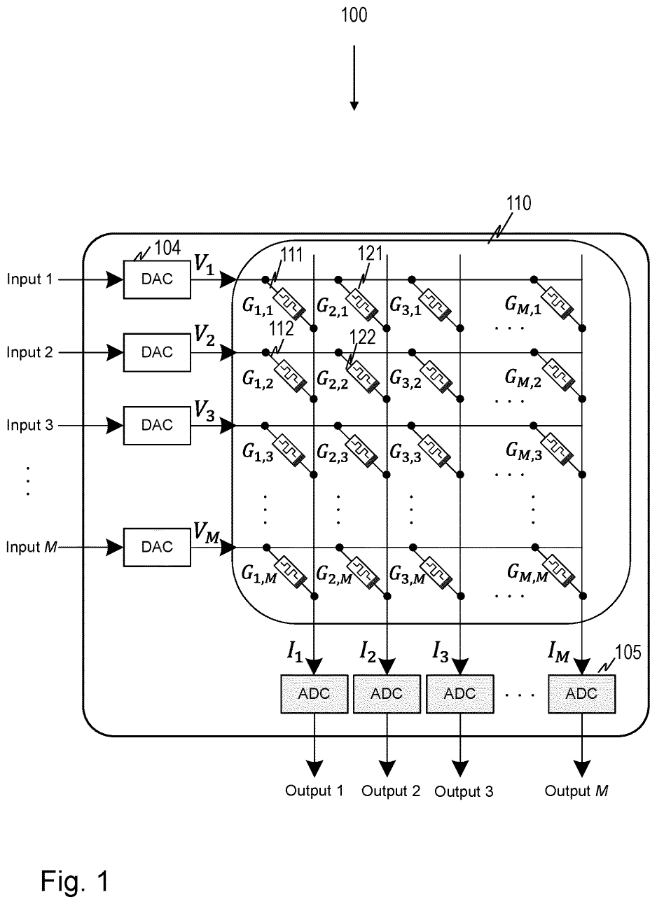

In a reference solution the entries of a transform matrix G (an M×M matrix) are programmed to the memristive devices 111, 112, 121, 122 of the M×M crossbar array 110 of FIG. 1 while the input vector V (an M×1 vector) is applied to the crossbar rows. Note that, the vector V corresponds to the actual input vector (Input 1, . . . , Input M), which may be converted to analog voltages using Digital to Analog Converter (DAC) modules 104 illustrated in FIG. 1. As a result, the following MVM may be realized using the illustrated crossbar array 110,

$${I}_{i} = {\sum }_{j = 1}^{M} {G}_{i , j} {V}_{j} \qquad ( 2 )$$

$$i , j = 1 , … , M$$

$$I = [ \begin{matrix}{I}_{1} \\ {I}_{2} \\ . \\ . \\ . \\ {I}_{M}\end{matrix} ]$$

where the vector I is the output current of crossbar columns, which may be converted to the corresponding binary words using ADC modules 105 as shown in FIG. 1. This conversion may be done either separately for each crossbar column (i.e., one ADC for each binary word) or in a time-multiplexed fashion and hence reduce ADC overhead (i.e., multiple bit lines may share one ADC 105).

In this disclosure vectors and matrices are represented using capital boldface letters while their entries are shown using normal letters.

As mentioned above, using the above reference solution where the M×M transform matrix is programmed to corresponding memristors of crossbar arrays will lead to a high number of memristors. For example, in case of a complex input and complex DFT coefficients the required number of memristors will be 4N² for the matrix vector multiplication.

Embodiments herein aim to lower the number of required memristors for a particular transform size.

Embodiments herein will now be described with continued reference to FIG. 2a. The computations of the transform, such as the DFT or IDFT, which are basically multiplications of the input samples by the twiddle factors are performed using the memristors. This computation is done based on Ohm's law and Krichhoff's current law. However, in order to reduce the number of memristors not all outputs are calculated by the memristors. Instead, embodiments herein utilize a symmetry between the twiddle factors which is used to reduce the number of twiddle factors to be programmed to the memristors and consequently reduce the size of the crossbars. More specifically in case of an N-point transform, such as an N-point DFT, only N/8 twiddle factors are programmed into the crossbars, which are

$${W}_{N}^{k} ,$$

where

$$k = 0 , … , \frac{N}{8} - 1 .$$

The remaining twiddle factors will be calculated based on the following symmetry properties of the twiddle factors:

$${W}_{N}^{k + N} = {W}_{N}^{k} \qquad ( 3 )$$

$${W}_{N}^{k + N / 4} = - {jW}_{N}^{k}$$

$${W}_{N}^{k + N / 2} = - {W}_{N}^{k}$$

$${W}_{N}^{k + 3 N / 4} = {jW}_{N}^{k} .$$

Embodiments will now be described assuming a complex input and complex transform coefficients which is the most general case. However, if the input is real (i.e., not complex), only the memristors of the first electronic device 210 are needed. Similarly, if the transform coefficients are real then only half of the memristors of each of the first and second electronic device 210, 220 are needed; that is only one of the parts are needed.

Thus, in the fully complex case a total size of the one or more analog crossbar arrays 201, 202, 203, 204 of the respective first and second electronic device 210, 220 is

$$N \times \frac{N}{4}$$

since there are N inputs and N/4 outputs. The one or more analog crossbar arrays 201, 202, 203, 204 of each of the first and second electronic device 210, 220 are programmed with the same transform coefficients. Since the transform coefficients are complex, the memristors of the first part 201, 203, e.g., the first

$$\frac{N}{8}$$

columns, are programmed with the real part of the transform coefficients and the memristors of the second part, e.g., the remaining columns

$$( next \frac{N}{8} columns ) ,$$

are programmed with the imaginary part of the transform coefficients.

As mentioned above, the first electronic device 210 is configured to receive the real part of the input signal and the second electronic device 220 is configured to receive the imaginary part of the input signal.

When the electronic input signal is digital then the electronic device 200 further comprises one or more DACs 214 adapted to convert the input signal of multiple samples to corresponding analog voltages V₁, V₂, . . . . V_{N}.

In other words, when the input signal of the N multiple samples is digital, the electronic device 200 may further comprise the DACs 214 configured to convert the digital input signal of the N multiple samples to the N analog voltages.

There may be one DAC 214 per input sample. In some other embodiments there may be less than one DAC 214 per input sample as one DAC 214 may be shared among several input samples by multiplexing. For example, two input samples may share the same DAC 214 as will be described in more detail below.

An output vector, e.g., I, is equal to the result of matrix-vector multiplication, i.e., I=G·V.

Output signals will be extracted from the bit lines (columns in FIG. 2a) of the crossbar array 210, 220. If the crossbar array 210, 220 is analog then the output values may be converted to digital values. Thus, the electronic device 200 may further comprise one or more ADCs 215 adapted to convert the output samples, comprising analog output current, to corresponding digital output values. In other words, the electronic device 200 may further comprise ADCs 215 configured to convert the output from the respective output conductor to a digital signal.

If analog signals are needed in a next block in the processing chain then the ADCs 215 may not be needed.

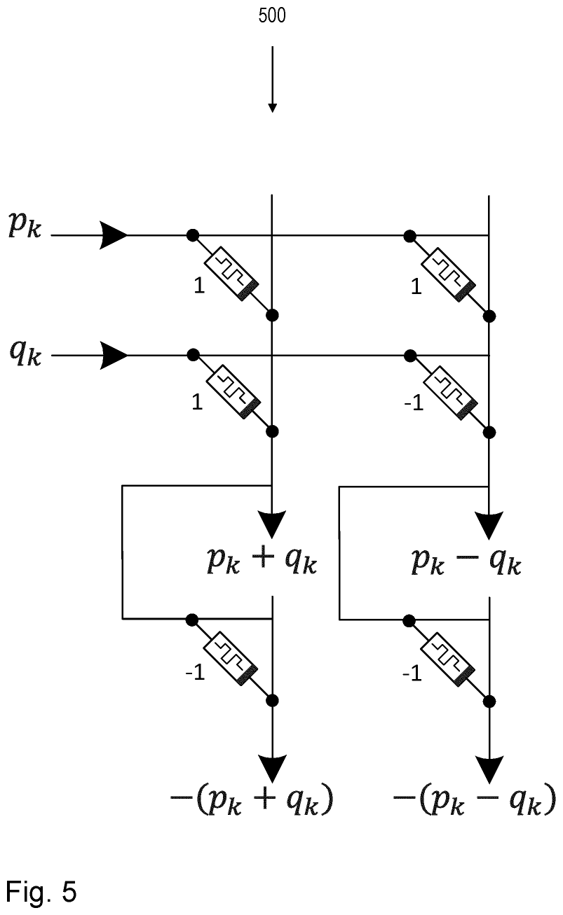

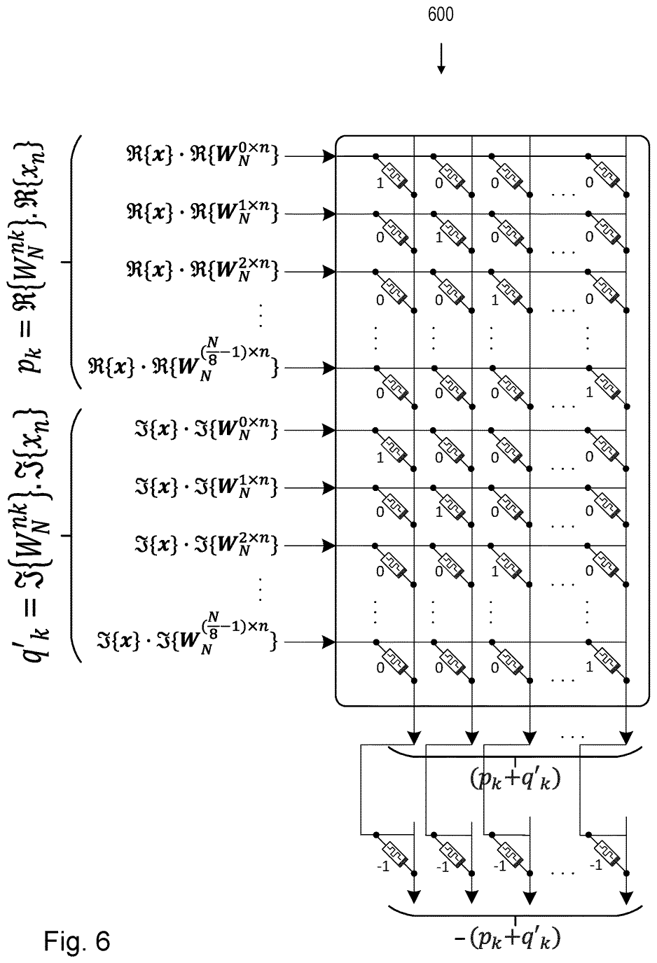

Further, if the analog outputs are sent to another crossbar array then they may be converted to voltage signals, which may be done by a resistor. This scenario will be described below in relation to FIG. 5 and FIG. 6.

FIG. 2b illustrates some embodiments herein in which the transform coefficients are real. Then only the first part 201, 203 of each crossbar array 210, 220 is needed. These embodiments correspond to DCT. an N-point DCT may be considered as a simplified case of and N-point DFT, in which

$${W}_{N}^{nk}$$

are real-domain coefficients for n=0, . . . , N−1 and k=0, . . . , N−1. As a result, the embodiments of FIG. 2b represent a simplified version of the embodiments in FIG. 2a. Since the DCT coefficients are real-valued numbers, the second part 202, 204 of the crossbar arrays are not used anymore. Thus, a required size of the respective crossbar array of each of the first electronic device 210 and the second electronic device 220 is

$$N \times \frac{N}{8} .$$

In total, DCT may require is

$$2 \times N \times \frac{N}{8}$$

memristors.

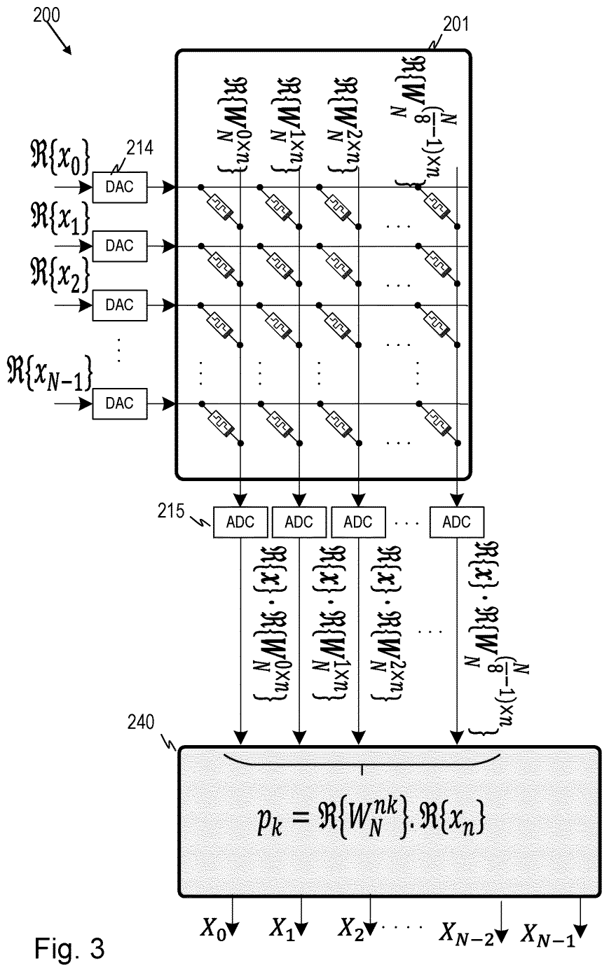

However, in many applications like image and video processing, the input samples are real values as well. Thus, in such a case, embodiments herein may be more simplified. In this case, only one crossbar of size N×N/8 is needed. FIG. 3 illustrates some embodiments herein in which the input is purely real and the transform coefficients are purely real. Thus, FIG. 3 illustrates the electronic device 200 for a DCT scenario and real input values. Then only the first part 201 of the first electronic device 210 is needed.

In order to simplify the description of embodiments herein, the following notation will be used for the twiddle factors,

$${a}_{nk} = \text{?} \{ {W}_{N}^{nk} \} , \qquad ( 4 )$$

$${b}_{nk} = \text{?} \{ {W}_{N}^{nk} \} ,$$

where

$$k = 0 , … , \frac{N}{8} - 1$$

and n=0, . . . , N−1. Also, the notation is simplified for the input samples as,

$${c}_{n} = ℜ \{ {x}_{n} \} , \qquad ( 5 )$$

$${d}_{n} = \text{?} \{ {x}_{n} \} .$$

As mentioned before, in the proposed scheme, the real and imaginary parts of the twiddle factors, aₙₖ and bₙₖ, are programmed in the first and second parts 201, 202, e.g., first and second

$$\frac{N}{8}$$

columns of both electronic devices 210, 220, respectively. Thus, the output values, generated in the first and second

$$\frac{N}{8}$$

columns of the first electronic device 210 are

$${p}_{k} = {\sum }_{n = 0}^{N - 1} {a}_{nk} \cdot {c}_{n} , \qquad ( 6 )$$

$${q}_{k} = {\sum }_{n = 0}^{N - 1} {b}_{nk} \cdot {c}_{n}$$

while the output values, which are produced in the first and second

$$\frac{N}{8}$$

columns of the second electronic device 220 are

$${p}_{k}^{′} = {\sum }_{n = 0}^{N - 1} {a}_{nk} \cdot {d}_{n} , {q}_{k}^{′} = {\sum }_{n = 0}^{N - 1} {b}_{nk} \cdot {d}_{n} . \qquad ( 7 )$$

The values of pₖ, p′ₖ, qₖ, and q′ₖ are calculated using the first electronic device 210 and the second electronic device 220 for

$$k = 0 , ... , \frac{N}{8} - 1$$

and n=0, . . . , N−1. The remaining values of pₖ, p′ₖ, qₖ, and q′ₖ for

$$k = \frac{N}{8} , ... , N - 1$$

are calculated by considering the symmetric property of the transform coefficients following (3) above. Finally, the output samples of the Fourier-related transform, Xₖ, are calculated as listed in Table 1 below.

TABLE 1
Generating output samples of the Fourier-related
transform based on the generated results from the crossbars.

| k | ${X}_{k} = {\sum }_{n = 0}^{N - 1} {W}_{N}^{nk} \cdot {x}_{n}$ |
|---|---|
| $0 \leq k \leq \frac{N}{8} - 1$ | (p + q′) + j(p′ − q) |
| $\frac{N}{8} \leq k \leq \frac{N}{4} - 1$ | (p′ + q) − j(p − q′) |
| $\frac{N}{4} \leq k \leq \frac{3 N}{8} - 1$ | (p′ − q) − j(p + q′) |
| $\frac{3 N}{8} \leq k \leq \frac{N}{2} - 1$ | −(p − q′) − j(p′ + q) |
| $\frac{N}{2} \leq k \leq \frac{5 N}{8} - 1$ | −(p + q′) − j(p′ − q) |
| $\frac{5 N}{8} \leq k \leq \frac{3 N}{4} - 1$ | −(p′ + q) + j(p − q′) |
| $\frac{3 N}{4} \leq k \leq \frac{7 N}{8} - 1$ | −(p′ + q) + j(p + q′) |
| $\frac{7 N}{8} \leq k \leq N - 1$ | (p − q′) + j(p′ + q) |

If the input signal is real then p′=0 and q′=0 which leads to the below simplified Table 2.

TABLE 2
Generating output samples of the Fourier-related
transform based on the generated results
from the crossbars when the input.

| k | ${X}_{k} = {\sum }_{n = 0}^{N - 1} {W}_{N}^{nk} \cdot {x}_{n}$ |
|---|---|
| $0 \leq k \leq \frac{N}{8} - 1$ | p − jq |
| $\frac{N}{8} \leq k \leq \frac{N}{4} - 1$ | q − jp |
| $\frac{N}{4} \leq k \leq \frac{3 N}{8} - 1$ | −q − jp |
| $\frac{3 N}{8} \leq k \leq \frac{N}{2} - 1$ | −p − jq |
| $\frac{N}{2} \leq k \leq \frac{5 N}{8} - 1$ | −p + jq |
| $\frac{5 N}{8} \leq k \leq \frac{3 N}{4} - 1$ | −q + jp |
| $\frac{3 N}{4} \leq k \leq \frac{7 N}{8} - 1$ | −q + jp |
| $\frac{7 N}{8} \leq k \leq N - 1$ | p + jq |

### Adder Tree

According to Table 1, there are four common terms in the calculation of the output samples of a general Fourier-related transform, such as DFT, as follows: p+q′, p′+q, p′−q, p−q′. These terms may be calculated by a circuit that performs addition, such as an adder tree, since the value of pₖ, p′ₖ, qₖ, and q′ₖ are already generated using the crossbar arrays.

The adder tree may be realized using for example binary additions or a further analog crossbar array.

Thus, the electronic device 200 further comprises an electronic circuit 240 configured to calculate N output samples of the discrete Fourier-related transform comprising eight subsets of output samples. Each subset of output samples comprises N/8 output samples. The electronic circuit 240 is configured to calculate a respective subset of output samples based on an output from a respective output conductor of the 2N/8 or N/8 output conductors and further based on a symmetry of the N×N transform coefficients. The electronic circuit 240 calculates all the eight subsets, e.g., in parallel, and thus all the N output samples of the discrete Fourier-related transform are calculated.

As mentioned above, in some embodiments herein the transform coefficients are complex. Then the electronic circuit 240 may be configured to calculate a respective subset of output samples by being configured to combine first output from a respective output conductor of the N/8 first output conductors with second output from a respective output conductor of the N/8 second output conductors according to a respective combining scheme for each subset of output samples. Such a combining scheme is for example given by Table 1 above.

As mentioned above, the respective combining scheme is based on the symmetry of the N×N transform coefficients. As further mentioned above, the respective combining scheme comprises an indication to select the first output as a real part or an imaginary part of a respective output sample or an indication to select the second output as the real part or the imaginary part of the respective output sample or both. That is, the combining scheme indicates whether p, q, p′ and q′ in Table 1 should be part of the real part of the output or the imaginary part of the output.

The sign of p, q, p′ and q′ is also given by Table 1. Thus, the respective combining scheme further comprises an indication of a sign for the respective output from the respective output conductor.

In some embodiments herein the electronic circuit 240 of the second electronic device 220 and the electronic circuit 240 of the first electronic device 210 is a common electronic circuit 240. As can be seen in Table 1, the common electronic circuit 240 may be configured to calculate the N output samples of the discrete Fourier-related transform by combining the first output from the respective output conductor of the N/8 first output conductors of the first electronic device 210 and the second output from the respective output conductor of the N/8 second output conductors of the first electronic device 210 with the first output from the respective output conductor of the N/8 first output conductors of the second electronic device 220 and the second output from the respective output conductor of the N/8 second output conductors of the second electronic device 220 according to a respective common combining scheme for each subset of output samples.

The respective common combining scheme may comprise an indication to select the respective first output as a real part or an imaginary part of a respective output sample or an indication to select the respective second output as the real part or the imaginary part of the respective output sample or both. The respective combining scheme may further comprise the indication of the sign for the respective output from the respective output conductor.

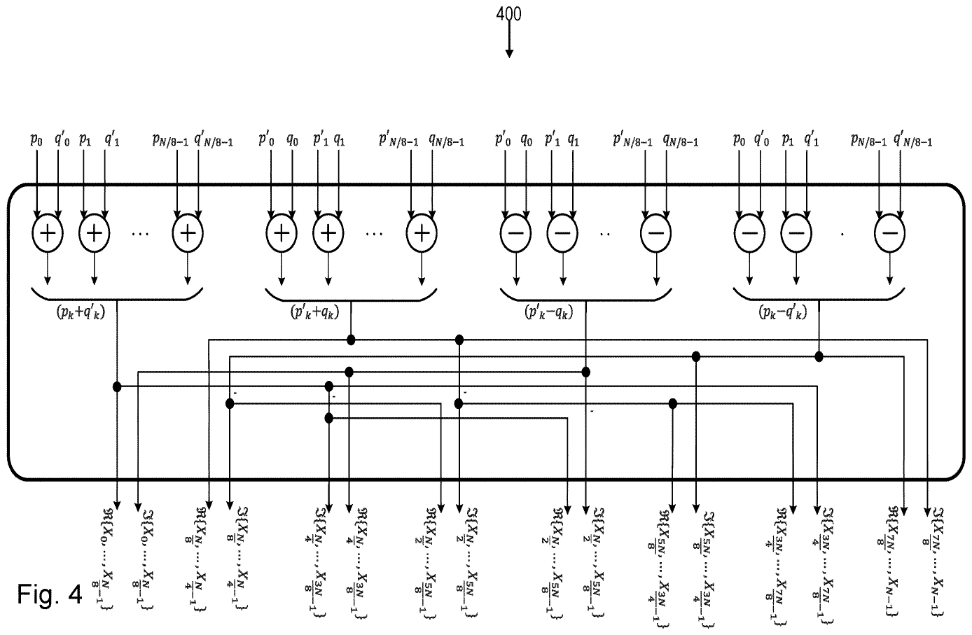

Examples of how the adder tree may be realized are presented below.
Digital-domain binary adder tree: In order to calculate these terms in parallel in the digital domain using binary adders, four groups of binary adders, each group of binary adders comprising N/8 adders, may be used as illustrated in FIG. 4. These perform addition for

$$2 \times \frac{N}{8}$$

terms. As a result, four sets of pₖ+q′ₖ, p′ₖ+qₖ, p′ₖ−qₖ, and pₖ−q′ₖ may be generated for

$$k = 0 , ... , \frac{N}{8} - 1.$$

Next, the/output samples of the Fourier-related transform may be obtained following Table 1.
Memristive-based Adder Tree (1^{st} scenario): A second approach to calculate the above-mentioned terms is to employ further analog crossbar arrays. To do so, each digital adder in FIG. 4 may be replaced with a memristive-based adder, which is shown in FIG. 5. As shown in FIG. 5, the result of addition and its negation are generated using two and one memristive elements, respectively. As a result, the adder tree in FIG. 2a may be realized by using

$$\frac{3 N}{2}$$

memristors. Thus a further crossbar array 500 illustrated in FIG. 5 may comprise 3N/2 memristive devices.
Memristive-based Adder Tree (2^{nd} scenario): A further solution to realize the adder tree is to employ four uniform further crossbar arrays to perform all of the additions and subtractions needed to generate four sets of pₖ+q′ₖ, p′ₖ+qₖ, p′ₖ−qₖ, and pₖ−q′ₖ for

$$k = 0 , ... , \frac{N}{8} - 1.$$

The size of each crossbar arrays is

$$( \frac{2 N}{8} + 1 ) \times \frac{N}{8} .$$

FIG. 6 shows a second further crossbar array 600, which calculates pₖ+q′ₖ and −(pₖ+q′ₖ) for

$$k = 0 , ... , \frac{N}{8} - 1$$

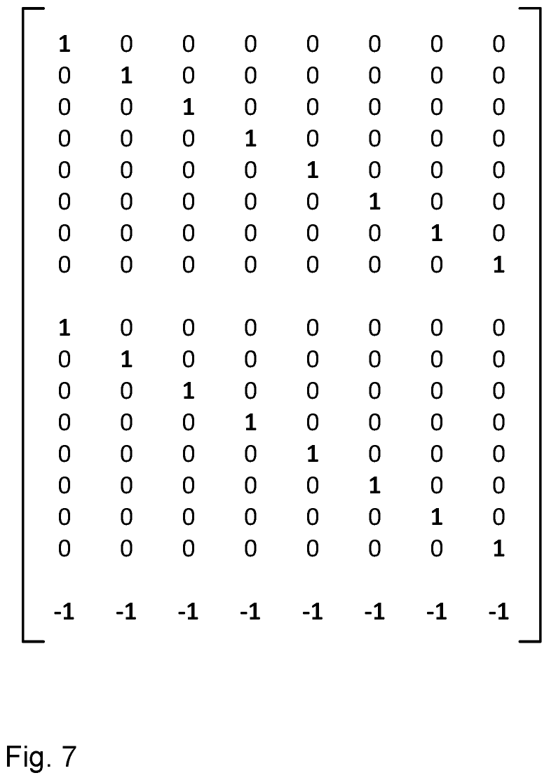

in parallel. FIG. 7 shows an example of a matrix, which will be used to program the crossbar array in FIG. 6 for a 64-point DFT (N=64). Having considered the structure of the matrix in FIG. 7, the first

$$\frac{2 N}{8}$$

crossbar rows perform addition to generate pₖ+q′ₖ for

$$k = 0 , ... , \frac{N}{8} - 1.$$

Then, the last row in FIG. 6, which includes

$$\frac{N}{8}$$

memristors, performs subtraction to generate −(pₖ+q′ₖ) for

$$k = 0 , ... , \frac{N}{8} - 1.$$

Thus, by employing four instances of the architecture in FIG. 6, the complete adder tree for an N-point DFT may be realized. The same matrix as the one in FIG. 7 may be used to program the second crossbar to generate p′ₖ+qₖ and −(p′ₖ+qₖ) for

$$k = 0 , ... , \frac{N}{8} - 1.$$

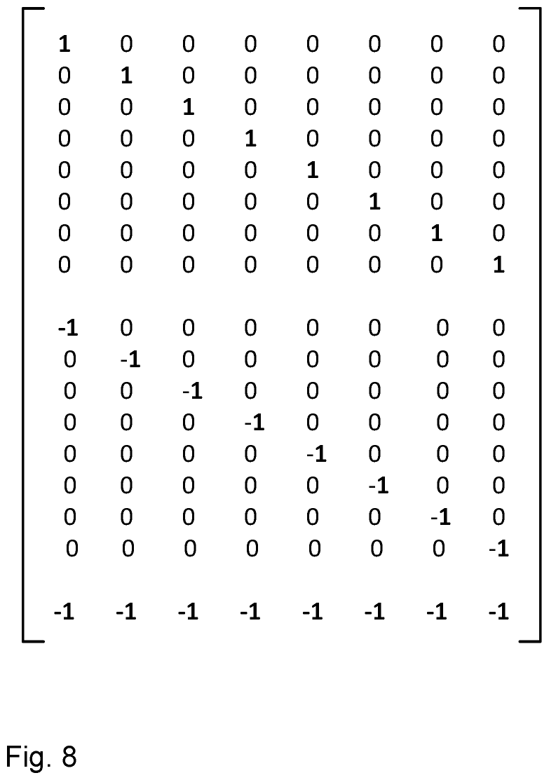

The third and fourth crossbars may be programmed by the matrix shown in FIG. 8 to generate pₖ−q′ₖ, −(pₖ−q′ₖ), p′ₖ−qₖ, and −(p′ₖ−qₖ) for

$$k = 0 , ... , \frac{N}{8} - 1.$$

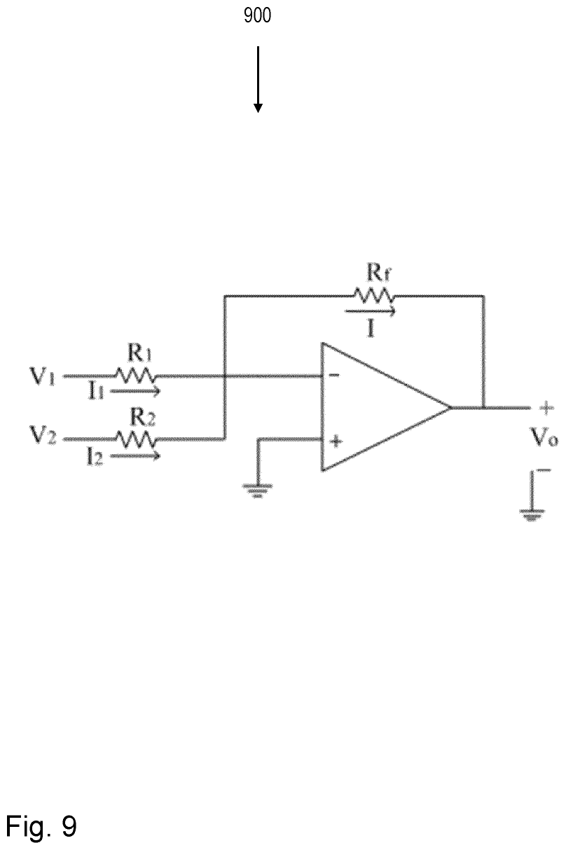

The second further crossbar array 600 may comprise: a) four crossbar arrays 600 each of size 2×N/8×N/8+N/8
Analog Adder Tree: Another alternative to implement the adder tree is to use an operational amplifier (Op-Amp) adder. An example of such a circuit is shown in FIG. 9, which performs addition of Vₒ=V₁+V₂.

In summary, the electronic circuit 240 may comprise any one or more of: A) binary adders 400, B) further crossbar arrays 500, or C) an operational amplifier 900.

Depending on whether an analog or digital adder tree is used, the ADCs 215 may be placed after or before the adder tree. Thus, if the adder tree is analog the ADCs 215 are placed after the adder tree. If the adder tree is digital the ADCs 215 are placed before the adder tree.

Further, if the analog outputs are sent to the further crossbar array 500 or the second further crossbar array 600 then they may be converted to voltage signals, which may be done by a resistor.

If the transform is DCT or IDCT the computations in Table 1 may be simplified such that all the terms of qₖ and q′ₖ are set to zero since they are related to the multiplication with the imaginary parts of the coefficients, which are zero for DCT/IDCT computation. Therefore, the DCT realization does not need an adder tree. Thus, only the last row in FIG. 5 or FIG. 6 is used to perform negation in case of DCT or IDCT.

Note that it is possible to employ multiple smaller crossbars instead of a single large crossbar to perform the same operations. Thus, any of the above four crossbars may be replaced with multiple smaller crossbars.

Further, in case of memristive-based and analog adder trees, the conversion to the digital domain will be done after the adder tree. Thus, if the digital adder tree is used, the ADCs will be placed before the adder tree as shown in FIG. 2a, FIG. 2b and FIG. 3 while if the analog adder tree is employed, the ADCs should be placed after the adder tree since the addition is performed in the analog domain.

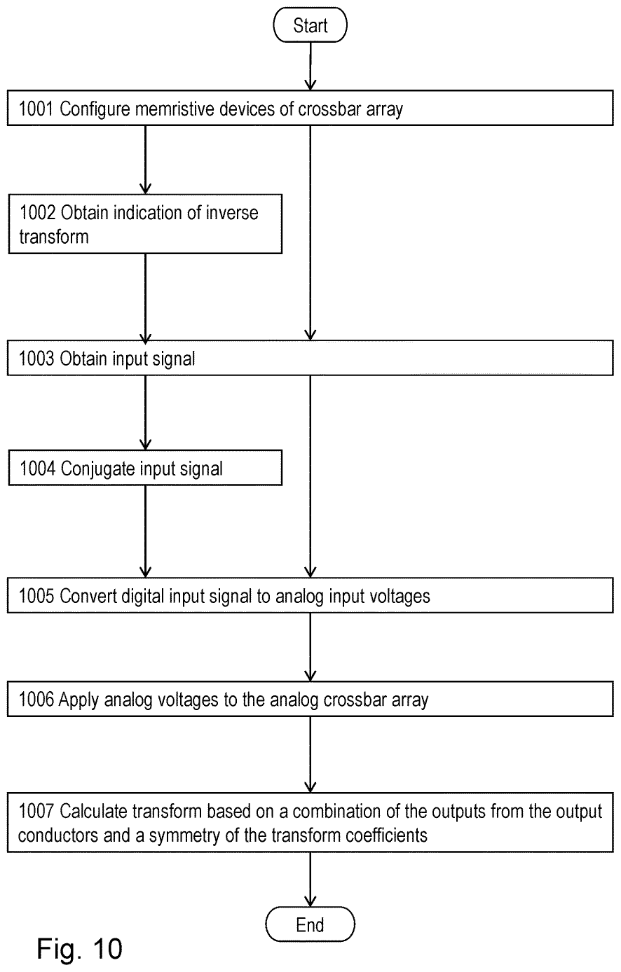

FIG. 10 illustrates a flowchart of a method for fully parallel discrete Fourier-related transform of an input signal of N multiple samples according to embodiments herein. N is a natural number of two or more. The method is performed by the electronic device 200. The electronic device 200 has been described above in relation to FIGS. 2-9.

In some embodiments herein the method is to be performed according to a DIT scheme. Then a transform matrix according to the DIT scheme may be a reordered transform matrix obtained by multiplying a first transform matrix comprising the N×N/8 sequential transform coefficients with an N×N reordering matrix. The multiplication of the first transform matrix with the reordering matrix may be performed offline since it is possible to know in advance if the system works with DIT or DIF. Due to the application of the reordering matrix an order of inputs and outputs are the same. Thus, there is no need for a reordering circuit for neither DIF nor DIT.

### Action 1001

The electronic device 200 may configure the memristive devices 211, 212, 221, 222 with the N×N/8 sequential transform coefficients.

### Action 1002

In some embodiments herein the electronic device 200 obtains an indication to perform an inverse transform.

### Action 1003

The electronic device 200 obtains the input signal of N multiple samples.

### Action 1004

In response to the indication to perform the inverse transform, the electronic device 200 may conjugate the input signal of N multiple samples before converting the input signal of the N multiple samples to N analog voltages using the N multiple DACs.

### Action 1005

In some embodiments the electronic device 200 converts the input signal of the N multiple samples to N analog voltages using N multiple DACs.

### Action 1006

The electronic device 200 applies the input signal to the analog crossbar array 201, 202. For example, the electronic device 200 applies the N analog voltages to the analog crossbar array 200.

If a further input signal comprises N′ multiple samples and N is larger than N′, the method may further comprise applying an n′:th sample of the further input signal of N′ multiple samples to an N/N′*i+1th DAC, wherein n′=1, . . . , N′ and i=0, . . . . N′−1.

### Action 1007

The electronic device 200 calculates N output samples of the discrete Fourier-related transform comprising eight subsets of output samples. Each subset of output samples comprises N/8 output samples. The electronic device 200 calculates a respective subset of output samples based on an output from a respective output conductor of the 2N/8 or N/8 output conductors and further based on a symmetry of the N×N transform coefficients.

If the further input signal comprises N′ multiple samples and N is larger than N′, then electronic device 200 may calculate N′ Discrete Fourier-related transform output samples of a discrete Fourier-related transform of the further input signal by obtaining output from an N/N′*i+1th column of the analog crossbar array 200.

Calculating the N output samples of the inverse transform may comprise conjugating calculated output samples and dividing each output sample with N.

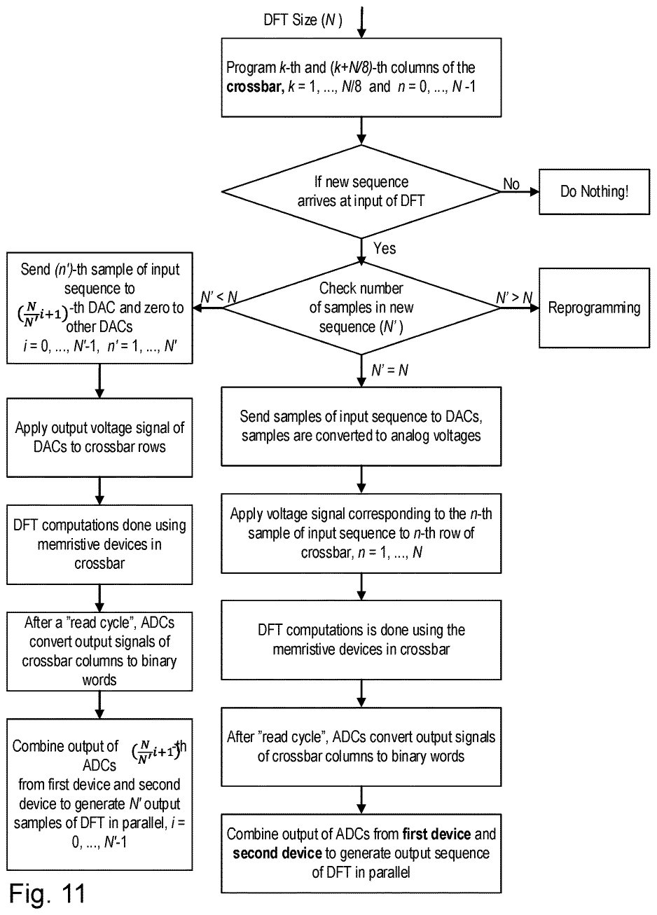

FIG. 11 illustrates a further flowchart of a method for fully parallel discrete Fourier-related transform performed by the electronic device 200.

FIG. 11 will be described by considering a scenario of a DFT of size N samples, where each sample is a complex value. It is assumed that two crossbar arrays of size

$$N \times \frac{N}{4}$$

are used to realize an N-point DFT. However, it is simply possible to consider four crossbars of size

$$N \times \frac{N}{8}$$

or even other sizes to realize an N-point DFT, meaning that embodiments disclosed below are independent of the crossbar size.

Let's consider two crossbars of size

$$N \times \frac{N}{4} ,$$

which are programmed with the same set of twiddle factors. Thus, the memristors of k-th and (k+N/8)-th columns of the first electronic device 210 and the second electronic device 220 are programmed with the real and imaginary parts of

$${W}_{N}^{( k - 1 ) n} ,$$

respectively, where k=1, . . . , N/8 and n=0, . . . , N−1. Thus, in each electronic device, the memristors of the first N/8 columns of the crossbar array may be programmed with the real part of the coefficient while the next N/8 columns may represent the imaginary parts of the coefficients. Having considered the above-mentioned crossbar setup, three scenarios may happen as described below.
1. the middle path of the flowchart of FIG. 11: If the size of the incoming sequence is equal to N samples, the samples may be sent to one or more DAC modules to be converted to the corresponding analog voltage signals. Then, the voltage signal corresponding to the n-th sample of the input sequence may be applied to n-th row of crossbar (n=1, . . . , N), where the DFT computations are done using the memristive devices following equation (1) above. After a “read cycle”, ADCs convert the output signals of crossbar columns to binary words. A read cycle corresponds to a time to produce the output signal once the input signal has arrived at the electronic device 200. The binary words from the first electronic device 210 and the second electronic device 220 will be combined together to generate the output samples of DFT in parallel.
2. Left path of the flowchart of FIG. 11: If the size of incoming sequence, N′, is less than N samples, the (n′)-th sample of the input sequence may be sent to

$$( \frac{N}{{N}^{′}} i + 1 )$$

-th DAC and “zero” is sent to the other DACs, where i=0, . . . , N′−1 and n′=1, . . . , N′. Next, the output voltage signals of DACs may be applied to the crossbar rows, where the DFT computations are done using the memristive devices following equation (1) above. After a “read cycle”, ADCs convert the output signals of crossbar columns to binary words. Finally, the binary words, which are generated in

$$( \frac{N}{{N}^{′}} i + 1 )$$

-th columns or the first electronic device 210 and the second electronic device 220 may be combined together to produce the output samples of DFT and the remaining words may be discarded.
3. the right path of the flowchart of FIG. 11: In case that the size of the incoming sequence is larger than N, a larger crossbar is needed. Thus, in this case the crossbar should be reprogrammed with a new set of coefficients.

### FURTHER DETAILED EMBODIMENTS

### Supporting Variable-Length DFT/IDFT

One of the features of embodiments disclosed herein is that they are flexible in terms of the length of the input sequence, such as the DFT size (N). More specifically, if the crossbar array is programmed to perform DFT/IDFT for a sequence of N samples, it may be used to perform DFT/IDFT for the sequences with smaller size, (N′) where N′<N. This feature is explained in detail in the left part of the flowchart of FIG. 11.

In such cases there is no need to create a new set of twiddle factors, which means that reprogramming is not needed.

Performing DFT and IDFT with the Same Hardware

The inverse discrete Fourier transform (IDFT) can be mathematically expressed as

$$\begin{matrix}x ( n ) = \frac{1}{N} {\sum }_{k = 0}^{N - 1} X ( k ) {W}_{N}^{- nk} & n , k = 0 , ... , N - 1 ,\end{matrix} \qquad ( 8 )$$

where

$${W}_{N}^{- nk}$$

is the complex conjugate of the twiddle factors, which were used to compute DFT in equation (1). This means that a new set of coefficients should be programmed to the crossbar arrays of the electronic device 200 to be able to perform IDFT.

Embodiments herein may perform both DFT and IDFT using the same hardware, e.g., the electronic device 200. An important point is that there is no need to reprogram the crossbar arrays to change the functionality from DFT to IDFT and vice versa. To this end the computation in equation (8) can be rewritten as

$$\begin{matrix}x ( n ) = \frac{1}{N} {\sum }_{k = 0}^{N - 1} {( {X}^{*} ( k ) {W}_{N}^{nk} )}^{*} & n , k = 0 , ... , N - 1.\end{matrix} \qquad ( 9 )$$

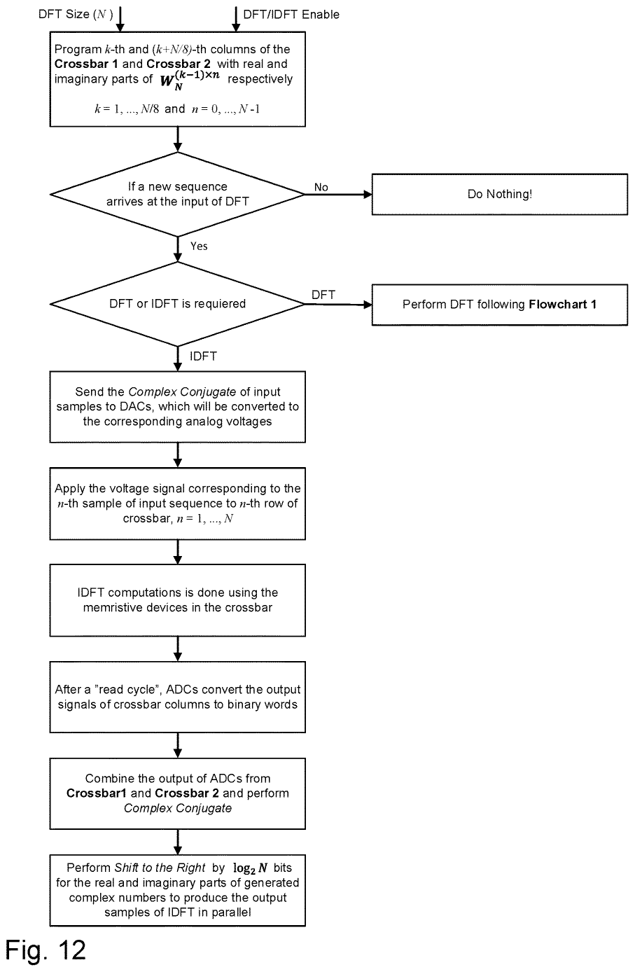

As a result, the DFT and IDFT may be performed using the same hardware, e.g., shown in FIG. 2a, and according to a method disclosed below describing a flowchart in FIG. 12.

### Description of IDFT Following the Flowchart of FIG. 12:

In a scenario the crossbar arrays of the electronic device 200 are already programmed to realize an N-point DFT as explained in the description of the flowchart of FIG. 11. As shown in the flowchart of FIG. 12, there may be an enable signal, which indicates if DFT or IDFT is needed. In case that DFT operation is needed, the computations will be done following the flowchart of FIG. 11. However, if an inverse Fourier-related transform, such as IDFT, is needed, a complex conjugate of the input samples may be applied to the DACs 214. These binary words will be converted to the corresponding analog voltage signals. Then, the voltage signal corresponding to the n-th sample of input sequence will be applied to n-th row of crossbar (n=1, . . . , N), where the IDFT computations are done using the memristive devices following equation (9). After a “read cycle”, the ADCs 215 convert the output signals of crossbar columns to binary words. The binary words obtained from the first electronic device 210 and the second electronic device 220 may be combined together following Table 1. Then, they will be conjugated and divided by N, which may be done by performing “Right Shift” by log₂ N bits to produce the output samples of IDFT in parallel.

Thus, the functionality of the crossbar may be alternated from DFT to IDFT by a modification of the imaginary parts of input and output samples.

The coefficient matrix and consequently the crossbar configuration may remain fixed regardless of DFT or IDFT.

### Supporting DIF and DIT Decompositions

A required decomposition scheme depends on the application. In case of DIF, the input samples of DFT are in natural order while the output samples are generated in bit-reversed order. In case of DIT, the input samples of DFT are in bit-reversed order while the output samples are produced in natural order. As a result, in prior art a reordering circuit is needed to reorder either the input samples in the DIT or the output samples in the DIF scheme.

However, an effect of embodiments disclosed herein is that the output samples are always generated in natural order for both DIF and DIT decomposition schemes. Thus, regardless of the order of input samples (i.e., DIF or DIT), a reordering circuit is not needed in embodiments herein.

Let's consider

$$W = [ {W}_{N}^{nk} ]$$

as a matrix of size

$$N \times \frac{N}{8} ,$$

which includes the required coefficients for computation of an N-point DFT following Table 1 (where n=0, . . . , N−1 and

$$k = 0 , ... , \frac{N}{8} - 1 ) .$$

In case of DIF decomposition, the crossbar of the first electronic device 210 and the crossbar of the second electronic device 220 may be programmed with the entries of W as described in Flowchart 1. Thus, the DFT is computed as

$$X = xW , \qquad ( 10 )$$

where x is the vector of input samples of size 1×N, W is the matrix of coefficients of size

$$N \times \frac{N}{8} ,$$

and X includes

$$\frac{N}{8}$$

output samples or DFT.

However, in case of DIT decomposition, the crossbar of the first electronic device 210 and the crossbar of the second electronic device 220 may be programmed with the entries of W′, which is the reordered version of W. This may be mathematically formulated as

$${W}^{′} = RW , \qquad ( 11 )$$

where R is an N×N reordering matrix and W′ is an

$$N \times \frac{N}{8}$$

matrix of coefficients, i.e., the same size as W. Having considered (10) and (11), the DFT is computed as

$$X = {x}^{′} {W}^{′} , \qquad ( 12 )$$

where x′ is the vector of reordered input samples, which is the case in DIT decomposition, i.e.,

$${x}^{′} = xR . \qquad ( 13 )$$

Since for a certain application it is known whether DIT or DIF is required, the programming of the crossbar of the first electronic device 210 and the crossbar of the second electronic device 220 may be done only once. As a result, there is no need to realize a separate reordering circuit in embodiments herein. This improves the hardware complexity and cost and latency of the DFT/IDFT considerably.

Note that the remaining output samples of both mentioned cases, i.e., outputs according to equation (10) and equation (12), will be generated based on Table 1.

### Supporting Large-Size DFT/IDFT

If the size of DFT/IDFT (N) is large such that the corresponding set of twiddle factors cannot be programmed to a single crossbar array. As mentioned in above, the total size of required crossbar is

$$N \times \frac{N}{2} ,$$

which may be divided into two crossbars of size

$$N \times \frac{N}{4}$$

or four crossbars of size

$$N \times \frac{N}{8} .$$

However if the size of available crossbar is less than

$$N \times \frac{N}{8} ,$$

it is possible to divide the set of twiddle factors into multiple smaller sets, which will be programmed to multiple crossbar arrays.

### Supporting Arbitrary-Size DFT/IDFT

Most of the traditional designs in the literature may realize DFT with the size of 2^{k}, e.g., 512, 1024, 2048, etc. The implementation of other DFT sizes using traditional approaches is very challenging since mix-radix and split-radix FFT algorithms are needed.

However, embodiments herein support realization of any DFT/IDFT sizes, which are not necessarily a power of two. Since embodiments herein are independent of the DFT radix, any arbitrary/strange DFT sizes may be realized without extra complexity or cost or both.

### Supporting Bit-Serial Inputs

The supported bit resolution of ADCs determines the quantization error; the higher supported bit resolution the lower the quantization error and hence the better performance. Therefore, in case that either the ADCs 215 do not support the required resolution or in order to improve the performance, each input sample of DFT/IDFT, which is a binary word, may be sent to the DACs 214 in a bit-serial manner. Thus, at each time instance, which corresponds to the read cycle of the crossbar array, one bit of all input binary-words is applied to the corresponding DACs 214. Therefore, after W read cycles, the DFT/IDFT computation is completed where W is the number of bits per input binary-word (input sample of DFTIDFT). In order to calculate the final result of DFT/IDFT in the bit-serial scheme, multiple “Shift and Add” circuits may be used after the ADCs 215 for each crossbar column.

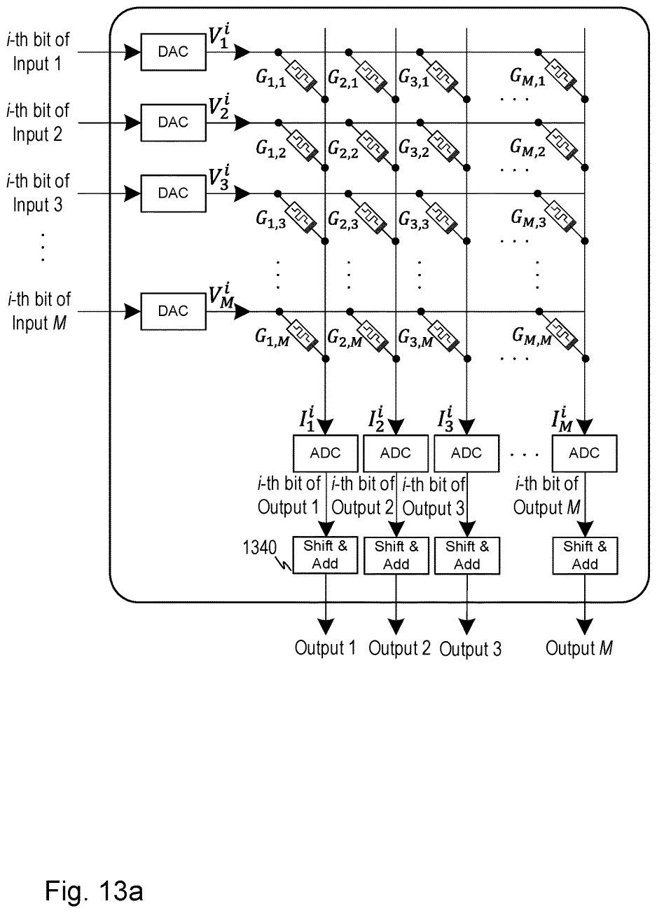

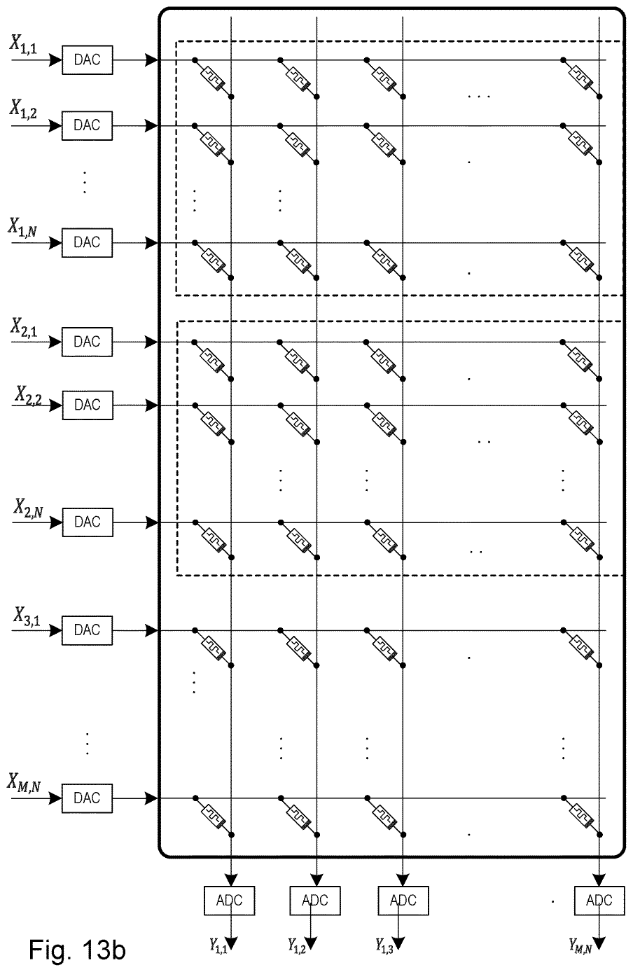

Thus, for the bit-serial adapted method, “Shift and Add” circuits may be used to calculate the final results of each crossbar column. Thus, the electronic device 200 may further comprise one or more digital shift and add circuits 1340 connected to a respective output of the one or more ADCs 215 in FIG. 13a. In other words, the electronic device 200 may further comprise a respective digital shift and add circuit 1340 after the ADCs 215 for each output conductor.

A bit-serial example will be given now. In the example the electronic device 200 comprises a crossbar array with 3 rows and one column programmed by C1, C2, C3. The inputs are represented by two bits.

In this example, in the first read cycle one bit of the inputs enter to the corresponding row and the resulting first output from the column is Out1=(0/1)×C1+(0/1)×C2+(0/1)×C3. In the second cycle, the second bit of inputs enter, and the resulting second output from the column is Out2=(0/1)×C1+(0/1)×C2+(0/1)×C3.

So far, the mentioned computations were done by the memristors. The final result is Out1+2×Out2. This computation is performed by adding and shifting, for example by the one or more digital shift and add circuits 1340. In this specific example, one shift and add circuit is enough since the crossbar has only one column. In general, one shift and add circuit per column may be needed unless they are time multiplexed between multiple columns to reduce the hardware cost. Note that the second output is multiplied by two because the second bit-position of a binary word has twice weight as the first bit-position (LSB).

### Design Comparison

The proposed idea improves the hardware efficiency significantly compared to the memristor-based DFT kernels in the literature. Table 3 compares the number of required memristors and adders in embodiments herein and the designs in the literature. A total size of crossbar arrays in embodiments herein is 8 times smaller than the memristor-based DFTs found in the prior art.

TABLE 3
Hardware comparison with prior art.

| | | # Memristors in | |
|---|---|---|---|
| | Adder Tree | Crossbar 1 and | # Memristors or Adders |
| Design | Realization | Crossbar 2 | in Adder Tree |
| Embodiments herein | Using Memristors | $\frac{{N}^{2}}{2}$ | $\frac{3 N}{2}$ |
| | Using Binary Adders | — | $\frac{N}{2}$ |
| Prior art | Using Memristors | 4N² | 4N |
| | Using Binary | — | 2N |
| | Adders | | |

### Memristive-Based Multidimensional DFT/IDFT and DCT/IDCT

Multidimensional DFT/IDFT and DCT/IDCT are used in some applications including hyperspectral imaging coding systems, video coding algorithms, adaptive video coding, and 3-D Compression. Sometimes these transforms are called 2-D and N-D DFT/IDFT or 2-D and N-D DCT/IDCT.

Embodiments disclosed herein may be employed to realize multidimensional Fourier-related transforms such as multidimensional DFT/IDFT and DCT/IDCT. To this end, multiple instances of the proposed architecture in FIG. 2a, FIG. 2b or FIG. 3 may be connected together in a serial manner as illustrated in FIG. 13b. Moreover, in this case the crossbars may be programmed with different coefficient matrices. These coefficient matrices may be obtained from the corresponding equation of multidimensional DFT and DCT. This procedure is similar to the case of extracting twiddle factors for one-dimensional DFT, as described above.

It is possible to employ any other

$$\frac{N}{8}$$

successive twiddle factors and not necessary the first

$$\frac{N}{8}$$

twiddle factors. This is due to the properties of twiddle factors, which were presented in equation (3). For example, the crossbars may be programmed by the coefficients corresponding to

$$k = \frac{N}{8} , ... , \frac{2 N}{8} - 1$$

to calculate pₖ, p′ₖ, qₖ, and q′ₖ for

$$k = \frac{N}{8} , ... , \frac{2 N}{8} - 1$$

and then the remaining values of pₖ, p′ₖ, qₖ, and q′ₖ may be calculated following Table 1 above.

In embodiments herein the symmetric property of the twiddle factors is employed to reduce the number of coefficients to be programmed into the memristive devices. Thus, in embodiments herein only a small number of the twiddle factors will be programmed to the crossbar, which reduces the number of memristors and consequently the hardware cost without reducing the degree of parallelism and without throughput degradation.

As mentioned above, there is no need to perform reordering for the input and output samples of DFT/IDFT, which in turn reduces the hardware cost and latency significantly. The output samples of DFT are always in a natural order. This point is valid in case of both DIF and DIT decomposition schemes.

Embodiments herein enables the variable-length DFT computations without any additional cost and without reprogramming. As long as the crossbar array is programmed to realize an N-point DFT, it may perform any DFT size of 1, . . . , N points.

All presented properties for the DFT/IDFT in embodiments herein, such as supporting large size, variable and arbitrary length, multidimensional transform, inverse of the transform, mapping to multiple crossbars, etc. may also be applied specifically to the DCT/IDCT implementation and other Fourier-related transforms as well.

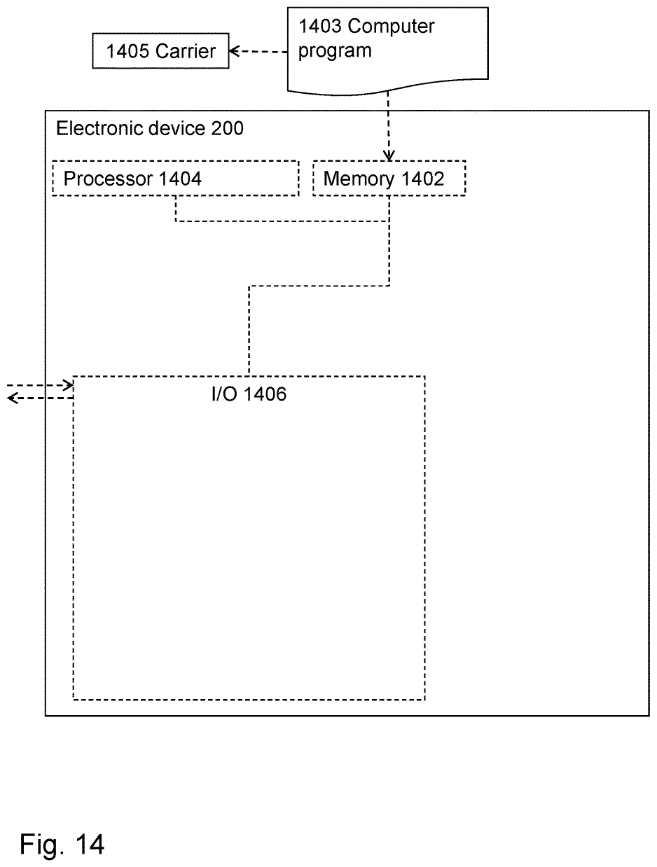

FIG. 14 illustrates further optional details of the electronic device 200. The electronic device 200 is configured to perform the method actions of FIG. 10 above.

The embodiments herein may be implemented through a processor or one or more processors, such as the processor 1404, of a processing circuitry in the electronic device 200, and depicted in FIG. 14 together with computer program code for performing the functions and actions of the embodiments herein. The program code mentioned above may also be provided as a computer program product, for instance in the form of a data carrier carrying computer program code for performing the embodiments herein when being loaded into the electronic device 200. One such carrier may be in the form of a CD ROM disc. It is however feasible with other data carriers such as a memory stick. The computer program code may furthermore be provided as pure program code on a server and downloaded to the electronic device 200.

The electronic device 200 may further comprise a memory 1402 comprising one or more memory units. The memory comprises instructions executable by the processor in the electronic device 200.

The respective memory 1002 is arranged to be used to store e.g. information, data, configurations, and applications to perform the methods herein when being executed in the electronic device 200.

In some embodiments, a computer program 1403 comprises instructions, which when executed by the at least one processor, cause the at least one processor of the electronic device 200 to perform the actions above.

In some embodiments, a carrier 1405 comprises the computer program, wherein the carrier is one of an electronic signal, an optical signal, an electromagnetic signal, a magnetic signal, an electric signal, a radio signal, a microwave signal, or a computer-readable storage medium.

The electronic device 200 may further comprise an input and output interface, I/O, 1406 configured to communicate with other devices. The input and output interface 1406 may comprise a receiver, such as a wireless receiver, (not shown) and a transmitter, such as a wireless transmitter, (not shown).

Those skilled in the art will also appreciate that the units described above may refer to a combination of analog and digital circuits, and/or one or more processors configured with software and/or firmware, e.g. stored in the electronic device 200, that when executed by the respective one or more processors such as the processors described above. One or more of these processors, as well as the other digital hardware, may be included in a single Application-Specific Integrated Circuitry (ASIC), or several processors and various digital hardware may be distributed among several separate components, whether individually packaged or assembled into a system-on-a-chip (SoC).

The electronic device 200 may be comprised in a node of a wireless communications network. For example, the electronic device 200 may be comprised in an access node such as a radio access node. In some other examples the electronic device 200 may be comprised in a wireless communications device. As mentioned above, there are other applications as well. For example, the electronic device 200 may be comprised in an electronic device for image and video signal processing.

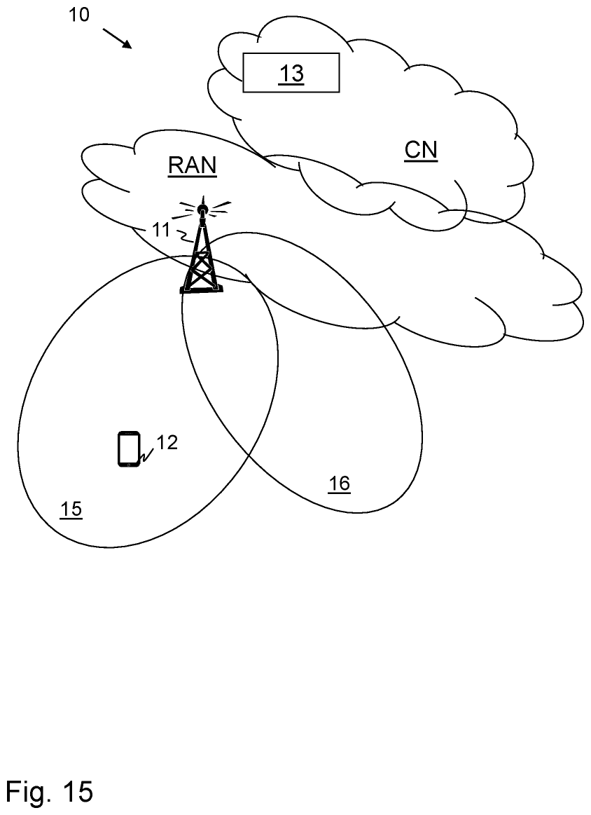

FIG. 15 illustrates a wireless communications network 10 in which embodiments herein may be implemented.

The wireless communications network 100 may use a number of different technologies, such as Wi-Fi, Long Term Evolution (LTE), LTE-Advanced, 5G, New Radio (NR), Wideband Code Division Multiple Access (WCDMA), Global System for Mobile communications/enhanced Data rate for GSM Evolution (GSM/EDGE), Worldwide Interoperability for Microwave Access (WiMax), or Ultra Mobile Broadband (UMB), just to mention a few possible implementations. Embodiments herein relate to recent technology trends that are of particular interest in a 5G context. However, embodiments are also applicable in further development of other existing wireless communication systems such as e.g. WCDMA and LTE and in future wireless communication systems, such as 6G systems.

Access nodes operate in the wireless communications network 100 such as a radio access node 11. The radio access node 11 provides radio coverage over a geographical area, a service area referred to as a cell 15, which may also be referred to as a beam or a beam group of a first radio access technology (RAT), such as 5G, LTE, Wi-Fi or similar. There may be more than one cell. For example, there may be a second cell 16 as well. The radio access node 11 may be a NR-RAN node, transmission and reception point e.g. a base station, a radio access node such as a Wireless Local Area Network (WLAN) access point or an Access Point Station (AP STA), an access controller, a base station, e.g. a radio base station such as a NodeB, an evolved Node B (eNB, eNode B), a gNB, a base transceiver station, a radio remote unit, an Access Point Base Station, a base station router, a transmission arrangement of a radio base station, a stand-alone access point or any other network unit capable of communicating with a wireless device within the service area depending e.g. on the radio access technology and terminology used. The respective radio access node 11 may be referred to as a serving radio access node and communicates with a UE with Downlink (DL) transmissions to the UE and Uplink (UL) transmissions from the UE.

A number of wireless communications devices operate in the wireless communication network 10, such as a wireless communications device 12.

The wireless communications device 12 may be a mobile station, a non-access point (non-AP) STA, a STA, a user equipment and/or a wireless terminal, that communicate via one or more Access Networks (AN), e.g. RAN, e.g. via the radio access node 11 to one or more core networks (CN) e.g. comprising a CN node 13, for example comprising an Access Management Function (AMF). It should be understood by the skilled in the art that “UE” is a non-limiting term which means any terminal, wireless communication terminal, user equipment, Machine Type Communication (MTC) device, Device to Device (D2D) terminal, or node e.g. smart phone, laptop, mobile phone, sensor, relay, mobile tablets or even a small base station communicating within a cell.

When using the word “comprise” or “comprising” it shall be interpreted as non-limiting, i.e. meaning “consist at least of”.

The embodiments herein are not limited to the above-described preferred embodiments. Various alternatives, modifications and equivalents may be used.

1.-17. (canceled)

18. An electronic device configured for a fully parallel discrete Fourier-related transform, the electronic device comprising:
an analog crossbar array comprising:
a set of N utilized input conductors for receiving N analog voltages corresponding to an input signal of N multiple samples, wherein N is a natural number that is a multiple of eight; and
a set of output conductors electrically connected to the set of N input conductors via an array of memresistors such that each output conductor is connected to a respective input conductor via a respective memresistor, wherein:
each memresistor is configured to represent at least a part of a respective transform coefficient out of N×N/8 sequential transform coefficients of a total of N×N transform coefficients of the discrete Fourier-related transform,
when the transform coefficients are complex, 2×N/8 of the output conductors and 2×N×N/8 of the memresistors are utilized for the discrete Fourier-related transform of the input signal, and
when the transform coefficients are real or imaginary, N/8 of the output conductors and N×N/8 of the memresistors are utilized for the discrete Fourier-related transform of the input signal; and
an electronic circuit configured to calculate N output samples of the discrete Fourier-related transform, wherein:
the N output samples comprise eight subsets of N/8 output samples, and
the electronic circuit is configured to calculate the respective subsets of output samples based on the following: respective outputs from the 2N/8 or N/8 output conductors, and a symmetry of the N×N transform coefficients.

19. The electronic device according to claim 18, wherein:
the N×N transform coefficients are complex;
the 2×N×N/8 utilized memresistors comprise a first part of N×N/8 memresistors connected to N/8 first output conductors and a second part of N×N/8 memresistors connected to N/8 second output conductors,
the memresistors of the first part are configured to represent real parts of respective ones of the N×N/8 sequential transform coefficients,
each the memresistors of the second part are configured to represent respective imaginary parts of respective ones of the N×N/8 sequential transform coefficients,
the electronic circuit is configured to calculate the respective subsets of the output samples by combining first outputs from respective ones of the N/8 first output conductors with second outputs from respective ones of the N/8 second output conductors according to respective combining schemes for the respective subsets of output samples, wherein the respective combining schemes are based on the symmetry of the N×N transform coefficients, and
each combining scheme comprises:
an indication to select the first output as a real part or an imaginary part of a respective output sample or an indication to select the second output as the real part or the imaginary part of the respective output sample or both, and
an indication of a sign for the respective output from the respective output conductor.

20. An electronic device comprising:
a first electronic device according to claim 18, wherein the first electronic device is configured to receive a real part of the input signal; and
a second electronic device according to claim 18, wherein the second electronic device is configured to receive an imaginary part of the input signal.

21. The electronic device according to claim 20, wherein the electronic circuit of the second electronic device and the electronic circuit of the first electronic device are a common electronic circuit configured to calculate the respective subsets of the output samples by combining first outputs from respective ones of the N/8 first output conductors with second outputs from respective ones of the N/8 second output conductors according to respective combining schemes for the respective subsets of output samples, wherein:
the first outputs are generated by the first electronic device,
the second outputs are generated by the second electronic device, and
the respective combining schemes are based on the symmetry of the N×N transform coefficients, and
each combining scheme comprises:
an indication to select the first output as a real part or an imaginary part of a respective output sample or an indication to select the second output as the real part or the imaginary part of the respective output sample or both, and
an indication of a sign for the respective output from the respective output conductor.

22. The electronic device according to claim 21, wherein the common electronic circuit comprises one or more of the following: one or more binary adders, one or more further crossbar arrays, or an operational amplifier.

23. The electronic device according to claim 22, wherein one of the following applies:
the one or more binary adders comprise four groups of N/8 binary adders; or
the one or more further crossbar arrays comprise one of the following: four crossbar arrays, each of size 2×N/8×N/8+N/8; or 3N/2 memresistors.

24. The electronic device according to claim 18, further comprising Analog to Digital Converters (ADCs) connected to respective output conductors and configured to convert outputs from the respective output conductors to a respective digital signals.

25. The electronic device according to claim 24, further comprising digital shift and add circuits connected to respective outputs of the ADCs.

26. The electronic device according to claim 18, wherein the input signal of the N multiple samples is digital and the electronic device further comprises one or more Digital to Analog Converters (DACs) configured to convert the N multiple samples to the N analog voltages.

27. A method performed by electronic device configured for a fully parallel discrete Fourier-related transform, the method comprises:
applying an input signal of N multiple samples to an analog crossbar array, wherein N is a natural number that is a multiple of eight, wherein the analog crossbar comprises:
a set of N utilized input conductors for receiving N analog voltages corresponding to the input signal of N multiple samples; and
a set of output conductors electrically connected to the set of N input conductors via an array of memresistors such that each output conductor is connected to a respective input conductor via a respective memresistor, wherein″
each memresistor is configured to represent at least a part of a respective transform coefficient out of N×N/8 sequential transform coefficients of a total of N×N transform coefficients of the discrete Fourier-related transform,
when the transform coefficients are complex, 2×N/8 of the output conductors and 2×N×N/8 of the memresistors are utilized for the discrete Fourier-related transform of the input signal, and
when the transform coefficients are real or imaginary, N/8 of the output conductors and N×N/8 of the memresistors are utilized for the discrete Fourier-related transform of the input signal; and
calculating N output samples of the discrete Fourier-related transform, wherein:
the N output samples comprise eight subsets of N/8 output samples, and
the respective subsets of output samples are calculated based on the following:
respective outputs from the 2N/8 or N/8 output conductors, and a symmetry of the N×N transform coefficients.

28. The method according to claim 27, further comprising:
converting the input signal of the N multiple samples to N analog voltages using N multiple DACs; and
applying the N analog voltages to the analog crossbar array.

29. The method according to claim 28, further comprising:
obtaining an indication to perform an inverse transform;
obtaining the input signal of N multiple samples; and
in response to the indication to perform the inverse transform, conjugating the input signal before converting the input signal to N analog voltages using the N multiple DACs,
wherein calculating the N output samples of the inverse transform comprises conjugating calculated output samples and dividing each output sample by N.

30. The method according to claim 28, further comprising configuring the memresistors with the N×N/8 sequential transform coefficients.

31. The method according to claim 27, wherein:
the method is performed according to a Decomposition In Time (DIT) scheme, and
a transform matrix according to the DIT scheme is a reordered transform matrix obtained by multiplying a first transform matrix comprising the N×N/8 sequential transform coefficients with an N×N reordering matrix.

32. The method according to claim 27, further comprising:
applying an n′:th sample of a further input signal of N′ multiple samples to an (N/N′*i+1)th DAC, wherein n′=1, . . . , N′, i=0, . . . N′−1, and N′>N; and
calculating N′ Discrete Fourier-related transform output samples of a discrete Fourier-related transform of the further input signal by obtaining output from an (N/N′*i+1)th column of the analog crossbar array.

33. A non-transitory, computer-readable medium having stored thereon a computer program that, when executed by processing circuitry of an electronic device, causes the electronic device to perform the method according to claim 27.
